(19) United States
(12) Patent Application Publication
(10) Pub. No.: US 2006/0186406 A1
(43) Pub. Date: Aug. 24, 2006

(54) Method and system for qualifying a semiconductor etch process

(75) Inventors: Scott Gregory Bushman, Richardson, TX (US); Francis Gabriel Celii, Dallas, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/354,498

(22) Filed: Feb. 15, 2006

Related U.S. Application Data
(60) Provisional application No. 60/654,210, filed on Feb. 18, 2005.

(51) Int. Cl. H01L 21/66; H01L 23/58; H01L 21/84

(52) U.S. Cl. 257/48; 438/14; 438/151

(57) ABSTRACT

A method of manufacturing a semiconductor device by qualifying an etch process. A semiconductor substrate is subjected to a predefined etch process to produce a partially-etched film. A scatterometry signature of the partially-etched film is produced. The scatterometry signature is used to determine if a physical property of the partially-etched film matches a target result.

### CROSS-REFERENCE TO RELATED APPLICATIONS

This application claims the benefit of U.S. Provisional Application U.S. Provisional Application No. 60/654,210 entitled, “METHOD AND APPARATUS FOR THE QUALIFICATION OF A SEMICONDUCTOR THIN FILM PROCESS” filed on Feb. 18, 2005, and which is commonly assigned with the present invention, and incorporated by reference as if reproduced herein in its entirety.

### TECHNICAL FIELD

The invention is directed, in general, to a method of qualifying an etch process used for fabricating semiconductor devices, a system that incorporates the method, and a method of manufacturing an integrated circuit using the method or system.

### BACKGROUND

Etch processes are commonly used at several different stages in the fabrication of semiconductor devices. As device dimensions shrink to accommodate higher packing densities, more stringent requirements are placed on the precise control and maintenance of the etch process. Because there are many parameters that can affect the etch process, there are numerous opportunities for the process to be unintentionally altered from one run to the next. For example, changes to one or more of the chemical composition of the etchant formula, etch conditions (e.g., duration, pressure or temperature of the etch reaction), or the material properties of the production or sacrificial structures being etched, can significantly alter the structure resulting from the etch process.

For this reason, it is standard practice in the semiconductor industry for etch processes to be subjected to periodic qualifying. Conventional qualification procedures measure one or more of the physical properties of the target structure after the etch process is complete. Some qualification methods (e.g., profileometry, scanning electron microscopy (SEM), or atomic force microscopy (AFM)) involve the use of measurement techniques that may be slow or expensive. Some of these procedures entail destroying the structure being tested. Furthermore, certain procedures, such as profilometry, can have poor accuracy and repeatability and can only be used on large open areas, and not the dense patterned areas found in today's integrated circuits.

Moreover, qualifying an etch process by measuring the final target structure can have a number of drawbacks. For instance, an etch process that has drifted outside of its tolerance limits may not be detected until multiple defective wafers have already been produced. Additionally, examining the final target structure may not provide insight into the reasons for non-qualification. This, in turn, can necessitate the production and sacrifice of further test structures to ascertain what aspect of the etch process has changed.

Accordingly, what is needed is a method for qualifying etch processes that addresses the drawbacks of the prior art.

### SUMMARY

The invention provides a method of manufacturing a semiconductor device by qualifying an etch process. The method comprises subjecting a semiconductor substrate to a predefined etch process to produce a partially-etched film and producing a scatterometry signature of the partially-etched film. The method also comprises using the scatterometry signature to determine if a physical property of the partially-etched film matches a target result.

Another embodiment is an inspection system for qualifying an etch process in the manufacture of a semiconductor device. The system comprises a scatterometry tool comprising a light source and detector and a control module. The control module is configured to adjust an incident light applied by the light source to a partially-etched film of a semiconductor substrate and thereby produce a reflected light from the partially-etched film. The control module receives the reflected light from the detector as a function of the adjusted incident light and produce a scatterometry signature based on the received reflected light. The control module also determine if a physical property of the partially-etched film matches a target result based on the scatterometry signature.

Another embodiment is a method of manufacturing an integrated circuit. The method comprises partially etching a film on a semiconductor substrate using a predefined etch process and inspecting the partially-etched film. Inspecting comprises positioning a portion of the semiconductor substrate in the field of view of the scatterometry tool, producing the scatterometry signature and using the scatterometry signature to determine if a physical property of the partially-etched film matches a target result.

### BRIEF DESCRIPTION OF THE DRAWINGS

FIG. 1 presents a flow-diagram showing selected steps of an example method of qualifying an etch process according to the principles of the present invention;

FIG. 2 presents a block diagram of an example system for qualifying an etch process according to the principles of the present invention; and

FIGS. 3 to 5 present cross-sectional views of an example method of manufacturing an integrated circuit according to the principles of the present invention.

### DETAILED DESCRIPTION

Embodiments of the present invention benefit from the recognition that scatterometry can be used to qualify etch processes in semiconductor device fabrication. The term qualify as used herein refers to a test done to ensure that a predefined etch process implemented by an etching tool continues to perform the etch process to within acceptable tolerance limits in its fabrication of a target structure.

Scatterometry, by its optical nature, is nondestructive and fast. Consequently, scatterometry can be used as part of semiconductor device fabrication process to provide near real-time information about etch processes. This, in turn, allows tighter control over run-to-run variations in the etch process than possible using conventional qualification protocols. Additionally, scatterometry can test structures having the same density of semiconductor devices as the production material, or test the production material itself. This advantageously allows the detection of undesired variations in the etch process that otherwise would not be found had the qualification been done on low-density test structures.

Scatterometry performed for etch qualification can also provide additional information about the etched structure that is not obtained by some other qualification techniques. For instance, in addition to information about the rate at which the structure is being etched, scatterometry can provide estimates of the dimensions between different components of the structure and the properties of the material that the structure is composed of.

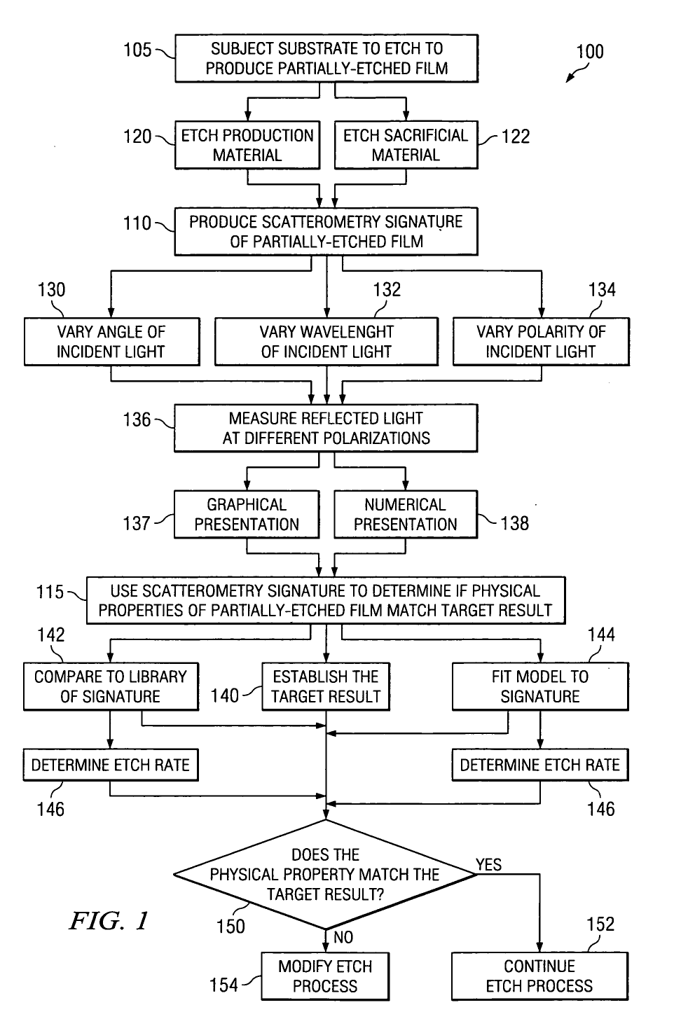

One embodiment is a method of manufacturing a semiconductor device by qualifying an etch process. FIG. 1 presents a flow-diagram showing selected steps of an example method 100 of qualifying the etch process. The method 100 comprises a step 105 of subjecting a semiconductor substrate to a predefined etch process to produce a partially-etched film. In step 110, a scatterometry signature of the partially-etched film is produced. The scatterometry signature is used, in step 115, to determine if a physical property of the partially-etched film matches a target result.

The semiconductor substrate etched in step 105 can be any material used in semiconductor device fabrication, such as a silicon wafer and various material layers thereon. The term predefined etch process as used herein refers to a procedure that has been established through previous studies to remove portions of a material used in the manufacture of the semiconductor device. The term partially-etched film as used herein is defined as any material layer or film that has been partially removed from the semiconductor substrate by the etch process to thereby form a grating within that material.

The partially etched film can be a production or sacrificial material. A production material is included in the final semiconductor device being fabricated. An example of production material is a layer or film used to form a gate, such as a polysilicon film. A sacrificial material is used in the fabrication of the semiconductor device, but is not part of the final device structure. An example of sacrificial material is a resist layer (e.g., a photoresist or hardmask).

The predefined etch process could be used at various steps in the fabrication of the components of the device. As an example, the predefined etch could comprise, in step 120, etching (e.g., a reactive ion etch) a production material (e.g., a polysilicon layer) to form a gate transistor. As another example, the predefined etch could comprise in step 122, etching (e.g., a plasma etch) a sacrificial material, such as a Titanium Aluminum Nitride (TiAlN) or Titanium Nitride (TiN) that is used as a hardmask layer to define an electrode of a capacitor.

The term grating as used herein is defined as a plurality (e.g., two or more) of raised structures comprising production or sacrificial material, where each of the raised structures are above a base layer that also made of the same production or sacrificial material. In some cases, the grating comprises a uniformly-spaced series of raised structures (e.g., lines or pillars). In some cases, the grating model contains physical properties of semiconductor device features for an integrated circuit. Non-limiting examples of suitable physical properties for modeling include the side-wall angle of raised structures, the spacing between, or height or thickness of the raised structures or base layer. In some cases, the grating corresponds to one or more of the actual components in the semiconductor device. For example, the raised features can correspond to transistor components (e.g., a polysilicon gate) or capacitor components (e.g., a capacitor electrode) of the semiconductor device. In other cases, the grating corresponds to photoresist or hardmask films or test components that are used in the fabrication the semiconductor device.

The scatterometry signature produced in step 110 refers to the change in the intensity of light reflected from the partially-etched film as a function of a changing characteristic of the incident light. The changing characteristic can be an angle of incidence (step 130), a wavelength (step 132) or a polarity (step 134) of the incident light. In some preferred cases, the intensity of reflected light is measured in step 136 at two or more polarizations (e.g., S and P polarizations). The scatterometry signature can be presented graphically, in step 137, as a plot of light intensity versus any of these characteristics, although a graphical presentation is not required. For instance, the scatterometry signature can be presented numerically, in step 138, as a series of data points in a data set.

The target result in step 115 is the expected physical properties of the partially-etched film if the etch process is working the same as previously established to produce the desired structure. For example, a target result established in step 140 can comprise the dimensions of geometric structures such as the expected spacing between the raised structures, the expected thickness of the raised structure, or expected the thickness of the base layer of the partially-etched film. Of course, because the production or sacrificial material is only partially etched, these physical properties are not necessarily the same as that of the final components of the semiconductor device.

In some cases, the target result established in step 140 comprises the index of refraction of the partially-etched film. As well known by those skilled in the art, the index of refraction (N) is given by the equation N=n−ik|_{λ}, where n is the index of refraction of the film at a particular wavelength λ of incident light, k is an extinction coefficient and i is an imaginary number. For example, when a variable angle-fixed wavelength scatterometry signature is obtained, the target result provided can be the value of n and k at wavelength λ of the incident light.

Those skilled in the art would understand how the scatterometry signature obtained from a partially-etched film can predictably depend upon several physical properties of the film. For instance, the spacing between raised structures, the thicknesses of the raised structures and of the base layer, the side-wall angle of the raised structures, and the refractive index of the film, all affect the scatterometry signature.

The relationship between such physical properties and the scatterometry signature can be established empirically or using theoretical models. See e.g., C. Raymond, “Scatterometry for Semiconductor Metrology”, in Handbook of Silicon Semiconductor Metrology, ed. A. C. Diebold, Marcel Dekker, pp. 485-495, (2001) (hereinafter “Raymond”), incorporated by reference herein in its entirety. Consequently, one or more of the physical properties of the partially-etched film can be determined by comparing the scatterometry signature to an empirically or theoretically generated library of signatures, or, by fitting a theoretical scatterometry model to the scatterometry signature.

For example, determining the physical property in step 142 can include a point-by-point comparison of the difference between the measured scatterometry signature data and members of the library of signatures. In some cases, it is desirable to use a comparison algorithm to facilitate locating a minimum in the root-mean-square-error (RMSE) or mean-square-error (MSE) of this difference. If a minimum is found and the RMSE or MSE in below a predefined value (e.g., RMSE or MSE of less that 3%, 2% or 0.5%, depending on the complexity of the scatterometry signature), then the partially-etched film is considered to have the physical property corresponding to the library signature that gave the minimum RMSE or MSE.

As another example, the physical property can be determined in step 144 by fitting a scatterometry model to the scatterometry signature. One of ordinary skill in the art would understand how to generate a scatterometry model. For example, the scatterometry model can be based on rigorous-coupled-wave theory. See e.g., Raymond. In the model, the physical properties corresponding to the partially-etched film (e.g., spacing, thickness, refractive index, etc. . . . ) are coefficients which are varied in the model to produce a theoretical scatterometry signature that best fits the scatterometry signature. Obtaining the best-fit can be facilitated by using an algorithm that performs regression or other forms of analysis, as embodied in a computer program. The partially-etched film is deemed to have physical properties that correspond to those coefficients that provide the best-fit of the scatterometry model to the scatterometry signature.

In some preferred embodiments, a layer immediately below the partially etched film has a refractive index that is at least about 10 percent different than a refractive index of the partially etched film. For instance, when the partially etched film comprises a TiAlN hardmask layer (n equal to about 1.890 at a λ of about 633 nm), the layer below the partially etched TiAlN hardmask layer preferably has an n that is greater than about 2.08 or less than about 1.70 at 633 nm. In some cases, e.g., the underlying layer comprises an iridium layer (refractive index equal to about 2.867 at 633 nm). Having an underlying layer with a different refractive index is advantageous in cases where one wishes to determine the refractive index of the partially etched film.

In some cases determining if the physical properties of the partially-etched film matches the target result includes determining, in step 146, an etch rate of the predefined etch process. For example, the etch rate can be calculated based on the change in thickness of the partially etched film, e.g. the base layer, and the duration of the etch process.

If it is decided, in step 150, that the physical properties of the partially-etched film matches the target result, then the etch process is qualified and the etch process is continued in step 152. In such cases, the predefined etch process can be continued on the same semiconductor substrate, and analogous substrates, until such time as it is deemed necessary to re-qualify the etch process. If it is decided, in step 150, that the physical properties of the partially-etched film do not match the target result, then the etch process is not qualified, and the etch process is modified in step 154. Those skilled in the art would be familiar with the variety of steps that could be taken to modify the etch process so as to make it qualified.

In some cases, the steps taken to modify the etch process is informed by the information gathered about the physical properties of the partially etched film in step 115. For example, if the index of refraction of the partially etched film determined in step 140 does not match the target result, this can indicate that the composition of the semiconductor substrate being subject to the etch process has changed. In this case, one of the steps taken to modify the etch process could be to modify the semiconductor substrate. As another example, if the etch rate determined in step 146 does not match the target result, then the etch process may be altered by changing the duration of the etch process, the concentration of the etchants used, or other parameters well know to those skilled in the art.

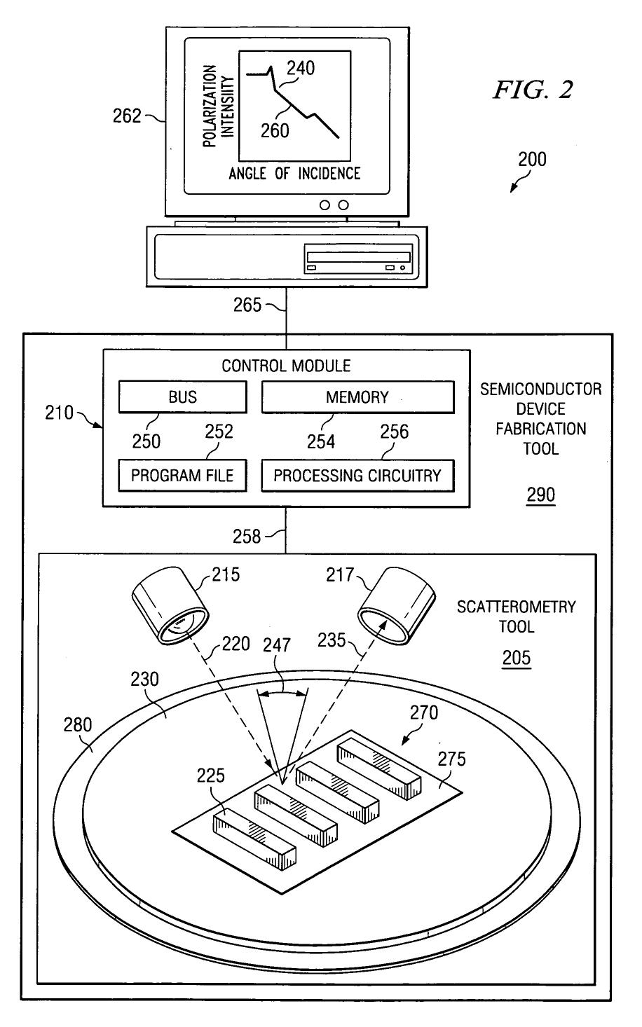

Another embodiment is an inspection system for qualifying an etch process in the manufacture of a semiconductor device. FIG. 2 presents a block diagram of an example inspection system 200 for qualifying an etch process according to the principles of the present invention. Any of the embodiments of the method discussed above in the context of FIG. 1 can be implemented by the system 200.

As illustrated in FIG. 2, the system 200 comprises a scatterometry tool 205 and a control module 210. The scatterometry tool 205 comprises a light source 215 and a detector 217. The control module 210 is configured to adjust an incident light 220 applied by the light source 215 to a partially-etched film 225 of a semiconductor substrate 230 and thereby produce a reflected light 235 from the partially-etched film 225. The control module 210 is also configured to receive the reflected light 235 from the detector 217 as a function of the adjusted incident light 220 and to produce a scatterometry signature 240 based on the received reflected light 235. As illustrated in FIG. 2, the scatterometry signature 240 can comprise a series of data points corresponding to a change in the light's polarization intensity, measured as a function of the angle of incidence 247 of the incident light 220.

The control module 210 comprises conventional processing devices capable of performing operations needed to control the inspection of semiconductor devices, and includes components well known to those skilled in the art. Such components can include a bus 250 to send commands to and receive data from the scatterometry tool 205, a program file 252 to control the scatterometry tool 205, a memory 254 to hold data obtained by the scatterometry tool 205, processing circuitry 256 to perform mathematical operations on the data, and a communication line 258 to the scatterometry tool 205.

The control module 210 is further configured to determine if a physical property of the partially-etched film 225 based on the scatterometry signature 240 matches a target result. For example, the processing circuitry 256 of the control module 210 can be configured to fit a scatterometry model (stored in the memory 254) to the scatterometry signature 240. As illustrated in FIG. 2, the scatterometry signature 240 and the best fit of the model 260 can be displayed on a video monitor 262 that is coupled to the control module 210 via a data cable 265.

Adjusting the incident light 220 applied can include positioning a portion 270 of the semiconductor substrate 230 in a field of view 275 of the scatterometry tool 205. The scatterometry tool 205 can have a stage 280 configured to position the portion 270 of the semiconductor substrate 230 in the field of view 275. In preferred embodiments of the system 200, the scatterometry tool 205 and control module 210 are configured to measure the scatterometry signal 240 from a portion 270 of the substrate 230 that has a density of raised features of the partially-etched film 225 that is substantially the same as the planned density of semiconductor device features in an integrated circuit design.

Some embodiments of the scatterometry tool 205 and control module 210 are components of a stand-alone inspection system 200, to which the semiconductor substrate 230 is transported to for the purposes of etch qualification. In other embodiments however, the inspection system 200 is part of a semiconductor device fabrication tool 290, such as a etching tool. Making the inspection system 200 part of the fabrication tool 290 can facilitate a more rapid qualification of the etch process by eliminating the time to transport the semiconductor substrate 230 to a stand-alone inspection system. Moreover, having the inspection system 200 as part of the fabrication tool 290 can facilitate more rapid modifications to the etch processes, when needed. For example, the control module 210 can be configured to send instructions to the fabrication tool 290 to modify one or more parameters of the etch process, such as an etch rate or the duration of etching.

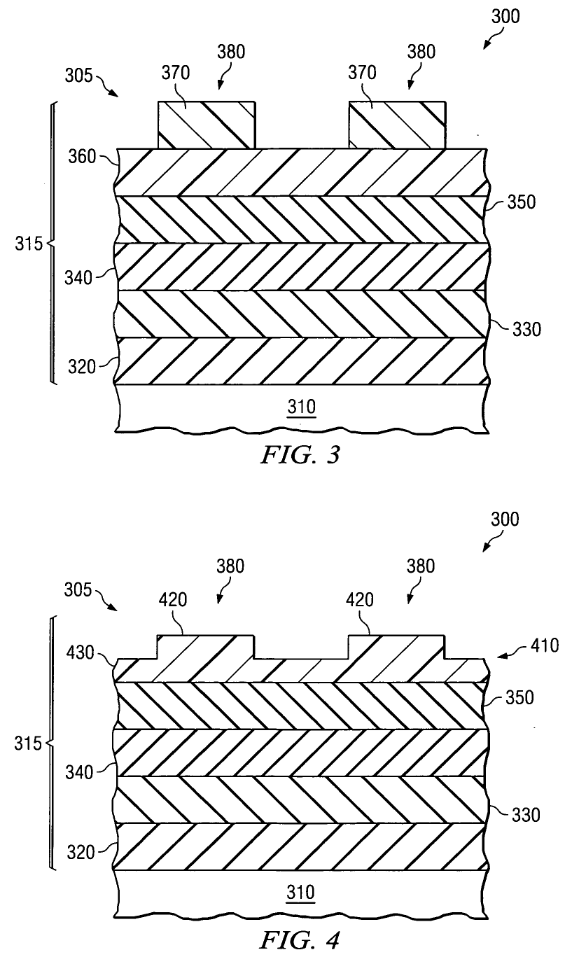

Another embodiment is a method of manufacturing an integrated circuit (IC). FIGS. 3-5 illustrate cross-sectional views of selected steps in an exemplary method of manufacturing an integrated circuit 300 according to the principles of the present invention. The method of manufacturing can comprise any embodiments of the method and systems discussed above in the context of FIGS. 1 and 2. Turning first to FIG. 3, illustrated is the partially completed integrated circuit 300 after partially forming a semiconductor device 305 on a semiconductor substrate 310.

Some preferred embodiments of the semiconductor device 305 comprise a capacitor, such as a ferroelectric random access memory (FRAM) capacitor. However, in other embodiments the semiconductor device 305 can comprise one or more transistors such as an nMOS and a pMOS transistor in a CMOS device, or a Junction Field Effect transistor, bipolar transistor, biCMOS transistor, or other conventional semiconductor device components, or combinations thereof. In still other preferred embodiments, however, the semiconductor device 305 can simply be a test structure configured to model certain structural attributes of one or more of the above-described functional devices.

As illustrated in FIG. 3, forming the semiconductor device 305 can include depositing a stack 315 of production or sacrificial films over the silicon wafer substrate 310, using conventional procedures such as chemical or physical vapor deposition. The stack 315 can e.g., comprise a silicon oxide film 330, a silicon nitride film 340, a second silicon oxide film 350, an iridium film 360, a hardmask film 360 and one or more photoresist film 370. FIG. 3 also shows the semiconductor device 305 after patterning the photoresist film 370 to define one or more device component structures 380 such as e.g., a capacitor electrode, of the device 305. Any conventional photoresist material and photolithographic method can be used to define the device component structures 380.

FIG. 4 presents the semiconductor device 305 after partially etching a film on a semiconductor substrate using a predefined etch process. The semiconductor device 305 is shown after removing the photoresist film 370 (shown in FIG. 3) by a conventional process, such as washing organic stripping agents or a dry plasma etch. Procedures, such as discussed above in the context of step 105 (FIG. 1), can be used to subject to substrate 310 to the predefined etch process thereby forming a partially etched film 410. For example, areas of the hardmask film 350 shown in FIG. 3 that are not covered by the photoresist film 360 can be partially etched via a plasma etch process configured to remove portions of a TiAlN or TiN hardmask film. The predefined etch process is continued for a period sufficient to form the partially etched film 410. For the device 305 shown in FIG. 4, the partially etched film 410 comprises raised structures 420 on a base layer 430, both the raised structures 420 and base layer 430 comprising the same material (e.g., the hardmask film 350 depicted in FIG. 3).

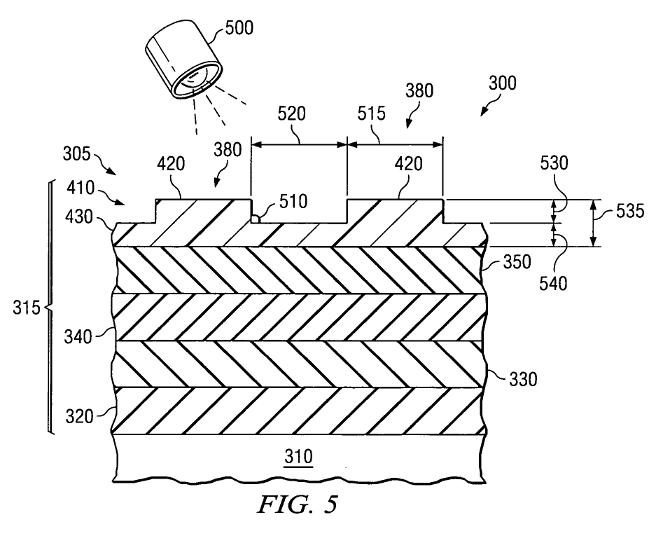

As shown in FIG. 5, the method includes inspecting the partially-etched film 410. The inspection can comprise any embodiments of the method and systems discussed above in the context of FIGS. 1 and 2. Inspecting, for example, can comprise positioning a portion of the semiconductor substrate 310 in a field of view of a scatterometry tool 500 analogous to the tool 205 presented in FIG. 2. A scatterometry signature of the partially-etched film 410 can be produced in accordance with step 110 in FIG. 1. The scatterometry signature can then be used, in accordance with step 115 to determine if a physical property of the partially-etched film 410 matches a target result. As noted in the context of FIGS. 1 and 2, examples of suitable physical properties include the side-wall angle 510 of the raised structures 420, the width 515 of the raised structures 420, the spacing 520 between raised structures 420, the height 530 or thickness 535 of the raised structures 420, the thickness 540 of the base layer 430, or the refractive index of the partially-etched film 410. For example, in some embodiments, where the partially-etched film 410 comprises TiAlN, the side-wall angle 510 ranges from about 55 to 75 degrees, the width 515 ranges from 400 to 700 nm, the spacing 520 ranges from 100 to 200 nm, the height 530 ranges from 100 to 200 nm, the base layer's thickness 540 ranges from 50 to 200 nm and the refractive index n and k range from about 1.59 to about 2.19, and from about 0.81 to about 1.41, respectively (λ equal to about 633 nm). These ranges for the partially etch film 410 are particularly conducive to accurate determinations of the physical properties from the scatterometry signature.

The target result can be expected ranges of values for any one or several of these physical properties, based on the characteristics of the predefined etch process, the material being etched, and the duration of the etch. As discussed above in the context of FIGS. 1-2, the predefined etch process can be altered if the physical properties do not match the target result, or continued, if physical properties match the target result.

1. A method of manufacturing a semiconductor device by qualifying an etch process, comprising:
subjecting a semiconductor substrate to a predefined etch process to produce a partially-etched film;
producing a scatterometry signature of said partially-etched film; and
using said scatterometry signature to determine if a physical property of said partially-etched film matches a target result.

2. The method of claim 1, wherein said partially-etched film comprises a production material of a semiconductor device.

3. The method of claim 1, wherein said partially-etched film comprises a sacrificial material used to fabricate a semiconductor device.

4. The method of claim 1, wherein a layer immediately below said partially etched film has a refractive index that is at least about 10 percent different than a refractive index of said partially etched film.

5. The method of claim 1, wherein said scatterometry signature comprises a set of reflected light intensities recorded at different angles of incident light.

6. The method of claim 1, wherein said scatterometry signature comprises a set of reflected light intensities recorded at different wavelengths of incident light.

7. The method as recited in claim 1, wherein said scatterometry signature comprises a set of reflected light intensities recorded at different polarities of incident light.

8. The method as recited in claim 1, wherein said scatterometry signature comprises a set of reflected light intensities recorded at two or more polarizations.

9. The method of claim 1, wherein determining if said physical property matches said target result comprises comparing said scatterometry signature to a library of signatures.

10. The method of claim 1, wherein determining if said physical property matches said target result comprises fitting a scatterometry model to the scatterometry signature.

11. The method of claim 1, wherein said physical property comprises a refractive index or an extinction coefficient.

12. The method of claim 1, wherein determining if said physical property matches said target result comprises determining an etch rate of said predefined etch process.

13. The method of claim 1, wherein said predefined etch process is altered if said physical property does not match said target result.

14. An inspection system for qualifying an etch process in the manufacture of a semiconductor device, comprising:
a scatterometry tool comprising a light source and detector; and
a control module configured to:
adjust an incident light applied by said light source to a partially-etched film of a semiconductor substrate and thereby produce a reflected light from said partially-etched film;
receive said reflected light from said detector as a function of said adjusted incident light;
produce a scatterometry signature based on said received reflected light; and
determine if a physical property of said partially-etched film matches a target result based on said scatterometry signature.

15. The system of claim 14, wherein adjusting said incident light includes positioning a portion of said semiconductor substrate in a field of view of said scatterometry tool.

16. The system of claim 15, wherein said field of view measures said reflected light from a region of semiconductor substrate having a density of raised features of the partially-etched film that is substantially the same as the planned density of semiconductor device features in an integrated circuit design.

17. The system of claim 14, wherein said control module is further configured to adjust an etch process to form said partially etched film if said physical property does not match said target.

18. A method of manufacturing an integrated circuit, comprising:
partially etching a film on a semiconductor substrate using a predefined etch process; and
inspecting said partially-etched film by:
positioning a portion of said semiconductor substrate in a field of view of a scatterometry tool;
producing a scatterometry signature of said partially-etched film; and
using said scatterometry signature to determine if a physical property of said partially-etched film matches a target result.

19. The method of claim 18, wherein said predefined etch process is altered if said physical property does not match said target result.

20. The method of claim 18, wherein said predefined etch process is continued if said physical property matches said target result.
